(19) United States
(12) Patent Application Publication
(10) Pub. No.: US 2012/0242405 A1
(43) Pub. Date: Sep. 27, 2012

(54) Frequency-Desensitizer for Broadband Predistortion Linearizers

(76) Inventors: Younkyu Chung, Irvine, CA (US); Blythe Chadwick Deckman, Corona, CA (US); Michael Peter DeLisio, JR., Monrovia, CA (US)

(21) Appl. No.: 13/429,219

(22) Filed: Mar. 23, 2012

Related U.S. Application Data
(60) Provisional application No. 61/465,862, filed on Mar. 25, 2011.

(51) Int. Cl. H03F 1/26

(52) U.S. Cl. 330/149

(57) ABSTRACT

Systems, apparatus and methods that provide broadband predistortion linearizers including simple frequency desensitizers to maintain substantially the same predistortion in a relatively broad frequency band. For example, a broadband predistorter can include a nonlinear component to predistort the drive signal, and a simple frequency desensitizer to compensate the frequency dependence of the nonlinear component. In particular implementations, the nonlinear component can have a frequency dependent impedance that substantially changes across the broad operating bandwidth and the frequency desensitizer can include resistive and reactive elements, such as a resistor (R), an inductor (L), and a capacitor (C) in a resonator configuration, to compensate for the frequency-dependence of the nonlinear component in the broad operating bandwidth.

### CROSS REFERENCE TO RELATED APPLICATION

The present application claims the benefit of priority to U.S. Provisional Patent Application Ser. No. 61/465,862, filed Mar. 25, 2011, entitled, “A Low-Cost, Miniature, Broadband Linearizer Incorporating a Frequency-Desensitizing Network,” the entirety of which is incorporated by reference herein.

### BACKGROUND OF THE INVENTION

The present invention relates generally to the control of microwave and millimeter-wave signals, which are used in telecommunication and satellite communication systems, and more particularly, to a predistortion linearizer for use with microwave and millimeter-wave power amplifiers.

A predistortion linearizer is typically used to improve the linearity and efficiency of microwave and millimeter-wave power amplifiers. Microwave and millimeter-wave power amplifiers amplify microwave and millimeter-wave radio frequency (“RF”) signals having a frequency, e.g., in the range from about 1 GHz to about 100 GHz. The RF signal carries information over an allocated frequency bandwidth of a carrier signal. Satellite communication systems, for example, can carry information in a 1 GHz bandwidth on a carrier signal that can range in frequency from 5 GHz to 46 GHz.

In practical implementations, power amplifiers typically distort the signal at high power levels. Thus, the power amplifier is often operated at a moderate power level where its distortion is tolerable. The efficiency of the power amplifier, however, is not optimal at such moderate power levels. Most microwave or millimeter-wave power amplifiers approximate an ideal amplifier's input-to-output linear transfer characteristic only for very low levels of input drive signals. As the amplitude of the input drive signal increases, the magnitude of the power amplifier's gain typically drops, and its input-to-output transfer characteristic departs more and more from the ideal linear relationship. This is commonly referred to as amplitude modulation-to-amplitude modulation (AM-AM) conversion, which is one source of distortion in all practical power amplifiers.

The ideal power amplifier also has a constant phase shift between the input and output signals as a function of the input signal level. However, a real power amplifier varies (advances or lags) the phase of the signal as a function of the input signal's amplitude, in particular, at high output power. This is commonly referred to as amplitude modulation-to-phase modulation (AM-PM) conversion, which is another source of distortion in all practical amplifiers.

Linearization techniques have often been used, and several classes of linearizers have been developed, to compensate for such distortions in real power amplifiers. Some of these linearizers intentionally predistort the drive signal that is input to a power amplifier so as to compensate for the known distortion of that power amplifier. These “predistortion linearizers” (also referred to as “predistorters”) have AM-AM and AM-PM conversion characteristics that are “reciprocal” to those of the power amplifier. Thus, the combined effect of the predistorter and the power amplifier is a substantially linear input-output transfer characteristics with a substantially constant phase shift for all power levels.

Predistortion linearizers often use nonlinear devices such as diodes or transistors to generate the inverse transfer characteristic. These nonlinear devices typically show not only resistive but also reactive characteristics that generate inductive, capacitive or a combination of inductive and capacitive behavior at the operating frequencies. Furthermore, the reactive behavior depends not only on the drive level, but on the operating frequency as well. Such frequency-sensitive reactive behavior may substantially modify the AM-AM and AM-PM conversions of the predistortion linearizer leading to different conversion characteristics at different frequencies. Thus, the modified conversion characteristics may not fully compensate for, or even introduce more distortion in addition to, the distortion of the power amplifier. To avoid the unwanted distortion, the predistortion linearizers have been typically limited to operate on signals that carry information in a relatively narrow frequency bandwidth. For a broader frequency range, complex and expensive circuitry has been used to maintain the required predistortion in that broader range of frequencies.

### SUMMARY OF THE INVENTION

The present invention discloses broadband predistortion linearizers that use simple frequency desensitizing techniques to maintain substantially the same predistortion in a relatively broad frequency band. For example, a broadband predistorter can include a nonlinear component to predistort the drive signal, and a simple frequency desensitizer to compensate the frequency dependence of the nonlinear component. In particular implementations, the nonlinear component can have a frequency dependent impedance that substantially changes across the broad operating bandwidth and the frequency desensitizer can include resistive and reactive elements, such as a resistor (R), an inductor (L), and a capacitor (C) in a resonator configuration, to compensate for the frequency-dependence of the nonlinear component in the broad operating bandwidth.

In general, in one aspect, the invention provides a predistortion linearizer for providing predistorted signals to a power amplifier. The linearizer includes an input, a nonlinear component, a frequency desensitizer, and an output. The input is configured to receive a drive signal carrying information in a frequency band. The nonlinear component is coupled to the input and configured to predistort the drive signal as a function of the drive signal's amplitude, the nonlinear component having an impedance substantially changing in the frequency band. The frequency desensitizer is coupled in parallel with the nonlinear component and configured to compensate the impedance changes of the nonlinear component within the frequency band, and the output is configured to provide the predistorted drive signal.

In particular implementations, the frequency desensitizer can include a resonator with a capacitor, an inductor and a resistor, wherein the capacitor and the inductor can be connected in series or in parallel. The resonator can have a resonance frequency above the frequency band. The frequency band can have a fractional bandwidth that is larger than 50%, such as about 100%, or larger. The frequency band can be between about 1 GHz and 2 GHz. The predistortion linearizer can include two resistors that form a non-linear attenuator with the nonlinear component. The non-linear attenuator can include a π-shape or a T-shape attenuator. The predistortion linearizer can also include a first impedance transformer to provide impedance matching with the input and a second impedance transformer to provide impedance matching with the output. The nonlinear element can be configured to generate AM-AM and AM-PM conversion characteristics that are reciprocal to those of the power amplifier. The nonlinear element can includes a diode, a pair of anti-parallel diodes, or a transistor. The predistortion linearizer can include a bias circuit configured to bias the diode as a function of a variable supply voltage. The bias circuit can include a JFET. The frequency desensitizer can includes a varactor.

In particular embodiments, the invention may be implemented to realize one or more of the following advantages. With the frequency desensitizer, the predistortion linearizer may not be limited to cancelling unwanted distortion only in a narrow bandwidth. Thus, the predistortion linearizer may be useful for broadband or multiband applications. Such broadband predistortion linearizer may operate at low frequencies that are comparable to the bandwidth. For example, the bandwidth can be about the same as, or about a half or a third of the lower limiting frequency of the band. In microwave satellite communication systems, the broadband predistortion linearizer may operate in the low frequency L-band (1-2 GHz). With the frequency desensitizer, the broadband predistortion linearizer may be implemented using simple, small, and low-cost circuit elements that operate in the L-band. Accordingly, the broadband predistortion linearizer can operate before up-converting the signal to a high frequency (e.g., a frequency between about 5 GHz and 46 GHz) RF signal to avoid the cost of using expensive high-frequency circuit elements for the linearizer. The frequency desensitizer may enhance the bandwidth performance of the predistorter without using complex broadband sub-circuits, such as broadband signal dividers and combiners in conjunction with broadband distortion generators, which are often rather large and expensive due to their complexity. The broadband predistorter may be implemented without variable amplifiers or attenuators in front of the predistorter to adjust input signal level. The broadband predistorter may be implemented without frequency-dependent phase shifters and electrical signal delay lines. Using the frequency desensitizer may avoid adding extra components that are themselves frequency-sensitive and would make even more difficult to compensate the distortions of the microwave power amplifier in a wide frequency bandwidth. Using a simple R-L-C resonator, the frequency desensitizer enables a designer to design simple, inexpensive predistortion linearizers even for a very wide frequency bandwidth (e.g., one with more than 100% fractional bandwidth). Using the frequency desensitizer may also result in a very physically compact design.

With a frequency desensitizer implemented according to one or more aspects of the invention, a simple and low-cost broadband linearizer may be capable to maintain linearization of microwave and millimeter-wave amplifiers used in telecommunication, satellite communication, or other systems that require operation in a wide frequency bandwidth. Such a broadband predistorter can neutralize the distortion of a power amplifier's output signal by providing independent reciprocal AM-AM and AM-PM conversions in a broad frequency band of interest, which may include one or more operational frequency bands. The broadband predistorter linearizes the amplifier's nonlinear behavior within an allocated band by desensitizing the frequency-dependency of the nonlinear component and maintain the required inverse AM-AM and AM-PM conversions for all operational frequencies.

In particular embodiments, the invention may also be implemented by incorporating a variable resistor so that the predistortion linearizer can allow for the independent gain control (AM-AM conversion), while the independent phase control (AM-PM conversion) can be achieved by changing the capacitance of a variable capacitor. Furthermore, this invention may also be implemented to allow for a wide dynamic range (more than about 10 dB) of input drive power at which the reciprocal AM-AM and AM-PM conversion characteristic of the predistorter begins, thereby substantially eliminating the necessity of variable gain amplifiers or variable attenuators that are used to adjust the critical input (or output) power of the traditional linearizer. Due to these advantages and flexibilities, the broadband predistortion linearizer may be easily integrated into systems that use a variety of solid-state and vacuum-tube amplifiers which require different AM-AM and AM-PM conversion characteristics and deliver different output power levels.

### BRIEF DESCRIPTION OF THE DRAWINGS

The accompanying drawings, which are included to provide a further understanding of the invention and are incorporated in and constitute a part of this specification, illustrate particular embodiments of the invention and together with the description serve to explain different aspects and principles of the invention.

In the drawings:

FIG. 1 is a schematic block diagram illustrating an exemplary satellite communication system that includes a broadband predistortion linearizer according to one aspect of the invention.

FIGS. 2A-2C are schematic block diagrams illustrating exemplary implementations of broadband predistortion linearizers according to different aspects of the invention.

FIG. 3 is a schematic diagram illustrating exemplary frequency dependence of a nonlinear component that can be used in a broadband predistortion linearizer according to one aspect of the invention.

FIG. 4 is a schematic flow chart illustrating a method of operation by a predistortion linearizer according to one aspect of the invention.

FIG. 5 is a schematic flow chart illustrating a method to design a predistortion linearizer according to one aspect of the invention.

FIGS. 6A-10 are schematic block diagrams illustrating exemplary embodiments of broadband predistortion linearizers according to different aspects of the invention.

### DETAILED DESCRIPTION

Reference will now be made in detail to particular embodiments of the present invention, examples of which are illustrated in the accompanying drawings.

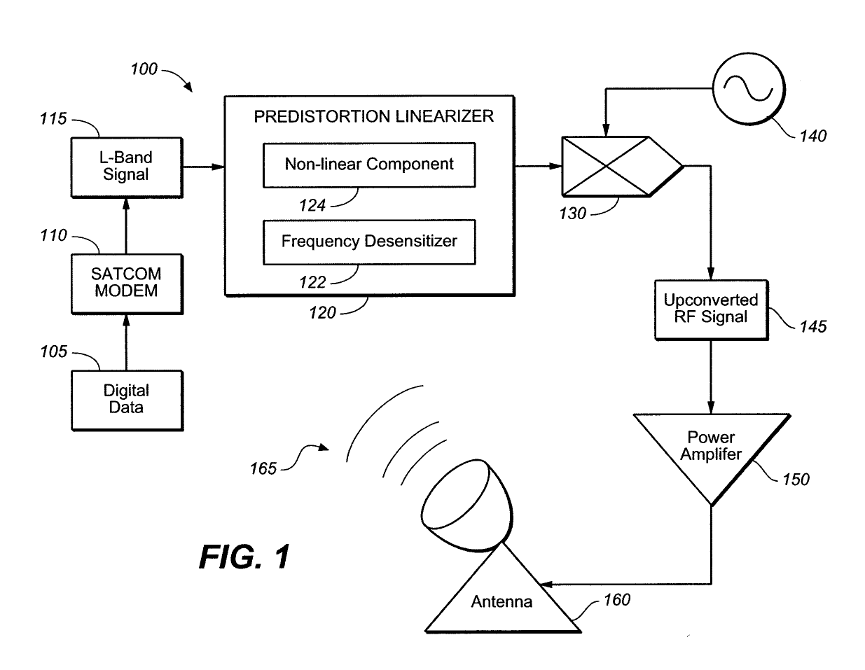

FIG. 1 is a schematic block diagram illustrating an exemplary satellite communication system 100 according to one aspect of the invention. The satellite communication system 100 receives communication information in the form of digital data 105 and transmits that information as an uplink signal 165 to a communication satellite (not shown). The satellite communication system 100 is only an exemplary system to illustrate different aspects of the present invention. Many of those aspects can be implemented in other systems to desensitize unwanted frequency dependence of certain components. For example, although the system 100 modulates information on L-Band signals, aspects of the invention can be implemented in systems that use other microwave or millimeter wave bands.

The satellite communication system 100 includes a SATCOM MODEM 110, a predistortion linearizer 120, an upconverter 130, a carrier signal source 140, a power amplifier 150, and an antenna 160. In the system 100, the signals are amplified without substantial distortions even though the power amplifier 150 itself generates AM-AM and AM-PM distortions at high power levels. To compensate for the distortions of the power amplifier 150, the system 100 includes the predistortion linearizer 120 which predistorts the signal “reciprocally” so that when the predistorted signal is distorted again by the power amplifier 150, the amplified signal becomes substantially undistorted even at large power levels.

In the system 100, the SATCOM MODEM 110 receives the communication information in the form of digital data 105 from which it generates an L-Band signal 115 that carries the communication information in a bandwidth between about 1 GHz and about 2 GHz. The predistortion linearizer 120 receives the L-Band signal 115 and predistorts it to compensate for the AM-AM and AM-PM distortions of the power amplifier 150. The predistorted signal from the predistortion linearizer 120 is upconverted by the upconverter 130 into an upconverted RF signal 145 using a carrier signal from the carrier signal source 140. For example, the upconverter 130 can upconvert the predistorted signal onto a carrier signal having a frequency from the range of about 5 GHz to 46 GHz. The upconverted RF signal 145 is amplified by the power amplifier 150, and the amplified RF signal is transmitted to the satellite as an uplink signal 165 by the antenna 160.

The predistortion linearizer 120 operates on the L-Band signal 115 and introduces AM-AM and AM-PM distortions that are substantially “reciprocal” to those of the power amplifier 150. The predistortion linearizer 120 includes a nonlinear component 124 and a frequency desensitizer 122. The nonlinear component 124 causes predistortions of the L-Band signal 115. Those predistortions, however, can substantially vary with the frequency in the L-Band. The frequency desensitizer 122 is configured to mitigate this frequency dependence so that the predestorion introduced by the linearizer 120 remains substantially the same in the entire L-Band.

The nonlinear component 124 can include, for example, one or more diodes or transistors, such as field effect transistors (FETs), bipolar junction transistors (BJTs) or any other type of transistors, that exhibit reactive (capacitive or inductive) behavior for signals in the L-Band. This reactive behavior can cause a strong frequency dependence in the impedance of the nonlinear component which, in turn, changes the predistortions caused by the nonlinear component 124. For example, the reactive part of the impedance of the non-linear component 124 can change by as much as about 100% or more, such as about 200%, across the frequency band of interest, in this case the L-Band. In addition to the changes in the reactance, the resistance of the nonlinear component 124 can also substantially change, by as much as about 100% or more, such as about 200%, across the frequency band of interest, in this case the L-Band.

The frequency desensitizer 122 can substantially compensate for the frequency dependence of the nonlinear component 124. In one implementation, the frequency desensitizer 122 can include resistive and reactive elements that are coupled, e.g., in parallel, to the nonlinear component 124. By properly selecting and tuning these resistive and reactive elements, the frequency desensitizer 122 can be configured to have impedance changes that substantially compensate for the effects caused by the impedance changes of the nonlinear component 124 across the frequency band of interest.

In one implementation, the frequency desensitizer 122 can include an R-L-C resonant circuit that shows relatively large impedance changes near its resonant frequency (determined by LC). By selecting the parameters of the R-L-C circuit appropriately, the frequency desensitizer 122 can be configured to provide the amount of impedance change that is required to compensate for the effects caused by the frequency dependent changes in the nonlinear component 124. For example, if the nonlinear component 124 has large impedance changes, the R-L-C circuit can have a resonant frequency close to the frequency band of interest to generate the large compensatory impedance changes in the frequency desensitizer 122 as well. If the nonlinear component 124 has smaller impedance changes, the R-L-C circuit can have a resonant frequency farther away from the frequency band of interest to generate less compensatory impedance changes in the frequency desensitizer 122 as well.

In the system 100, the predistortion linearizer 120 operates on the L-Band signal which has a large fractional bandwidth (of about 100%). The fractional bandwidth compares the bandwidth (of about 1 GHz) to the low-end frequency (of about 1 GHz) of the band, and can be informative about the degree of frequency dependence of the nonlinear element 124 in that band. For example, prior art systems used predistorters that acted on the upconverted RF signal 145 which has a carrier frequency from the range of about 5 GHz to 46 GHz. At that high RF frequency, the same absolute bandwidth of 1 GHz causes only a small relative change in the impedance of the nonlinear component 124. Because operating on a small fractional bandwidth (less than about 10%, the prior art predistorters did not need much frequency compensation. The prior art predistorters, however, have been more expensive because of the requirements of operating at the high RF frequency. In contrast, the predistortion linearizer 120 can be cheaper as it has a simple frequency desensitizer 122 which allows operation in a large fractional bandwidth at lower frequencies (at about 100% fractional bandwidth of the L-Band in the system 100).

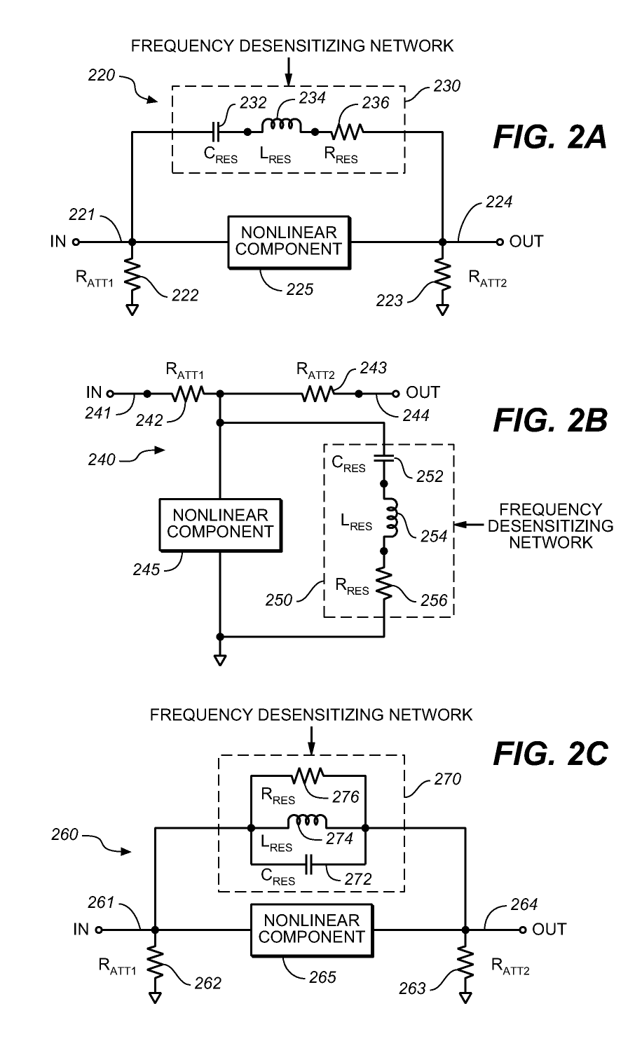

FIGS. 2A, 2B, and 2C illustrate exemplary implementations of respective broadband predistortion linearizers 220, 240, and 260, that can be used to implement the predistortion linearizer 120 in system 100 (shown in FIG. 1). Thus, the predistortion linearizers 220, 240, and 260 can be configured to predistort a drive signal for an RF power amplifier, such as the power amplifier 150 (shown in FIG. 1), which causes AM-AM and AM-PM distortions at high power levels. Instead of the system 100, the predistortion linearizers 220, 240, and 260 can also be used in other systems to desensitize unwanted frequency dependence of nonlinear circuit elements.

The predistortion linearizers 220, 240, and 260 include respective nonlinear components 225, 245, and 265 to generate predistortions. The impedance of the nonlinear components 225, 245, and 265, however, depends substantially on the frequency in the band of interest, such as a band that carries communication information (an example of which is the L-Band of FIG. 1). For example, the nonlinear components 225, 245, and 265 can include diodes or transistors that exhibit substantial variations in both resistive and reactive behavior at the different frequencies of the band. The predistortion linearizers 220, 240, and 260 include respective frequency desensitizing networks 230, 250 and 270, that can compensate for the changes in the impedance of the respective nonlinear components 225, 245, and 265.

In FIG. 2A, the predistortion linearizer 220 is implemented as a π-shape attenuator formed by resistors (R_{ATT1-2}) 222 and 223 that are connected by the non-linear component 225. The predistortion linearizer 220 receives an input signal at an input terminal 221 between the resistor 222 and the nonlinear component 225. The predistortion linearizer 220 outputs the predistorted signal at an output terminal 224 between the nonlinear component 225 and the resistor 223. In the predistortion linearizer 220, the frequency desensitizing network 230 is connected in parallel with the nonlinear component 225.

The frequency desensitizing network 230 includes a series R-L-C circuit formed by a capacitor (C_{RES}) 232, an inductor (L_{RES}) 234, and a resistor (R_{RES}) 236. The parameter values for the capacitor 232, inductor 234, and resistor 236 can be chosen to compensate for the frequency dependence of the nonlinear component's impedance in the frequency band of interest. For example, the R-L-C circuit's resonant frequency, which is determined by the capacitor 232 and the inductor 234, can be selected to be close to the frequency band of interest if the nonlinear component 225 has large impedance changes in that frequency band.

In FIG. 2B, the predistortion linearizer 240 is implemented as a T-shape attenuator formed by resistors (R_{ATT1-2}) 242 and 243 that are connected to one terminal of the non-linear component 245. The predistortion linearizer 240 receives an input signal at an input terminal 241 at one terminal of the resistor 242. The predistortion linearizer 240 outputs the predistorted signal at an output terminal 244 at a terminal of the resistor 243. In the predistortion linearizer 240, the frequency desensitizing network 250 is connected in parallel with the nonlinear component 245.

The frequency desensitizing network 250 includes a series R-L-C circuit formed by a capacitor (C_{RES}) 252, an inductor (L_{RES}) 254, and a resistor (R_{RES}) 256. The parameter values for the capacitor 252, inductor 254, and resistor 256 can be chosen to compensate for the frequency dependence of the nonlinear component's impedance in the frequency band of interest. For example, the R-L-C circuit's resonant frequency, which is determined by the capacitor 252 and the inductor 254, can be selected to be close to a frequency band of interest if the nonlinear component 245 has large impedance changes in that frequency band.

In FIG. 2C, the predistortion linearizer 260 is implemented as a π-shape attenuator formed by resistors (R_{ATT1-2}) 262 and 263 that are connected by the non-linear component 265. The predistortion linearizer 260 receives an input signal at an input terminal 261 between the resistor 262 and the nonlinear component 265. The predistortion linearizer 260 outputs the predistorted signal at an output terminal 264 between the nonlinear component 265 and the resistor 263. In the predistortion linearizer 260, the frequency desensitizing network 270 is connected in parallel with the nonlinear component 265.

The frequency desensitizing network 270 includes a parallel R-L-C circuit formed by a capacitor (C_{RES}) 272, an inductor (L_{RES}) 274, and a resistor (R_{RES}) 276. The parameter values for the capacitor 272, inductor 274, and resistor 276 can be chosen to compensate for the frequency dependence of the nonlinear component's impedance in the frequency band of interest. For example, the R-L-C circuit's resonant frequency, which is determined by the capacitor 272 and the inductor 274, can be selected to be close to the frequency band of interest if the nonlinear component 265 has large impedance changes in that frequency band.

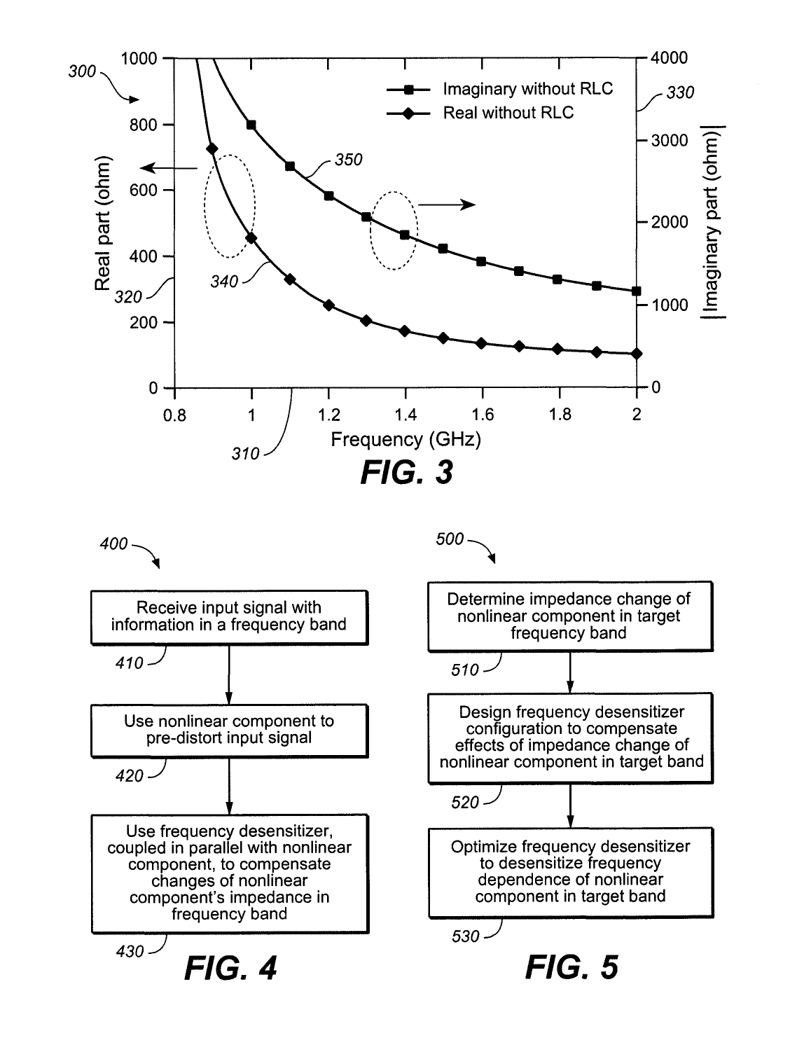

FIG. 3 shows a diagram 300 illustrating an exemplary frequency dependence of a nonlinear component's impedance. The exemplary frequency dependence can characterize nonlinear components 124, 225, 245 and 265 (shown in FIGS. 1 and 2A-2C) that can be used in a predistortion linearizer. For example, the exemplary impedance behavior shown in diagram 300 can characterize a nonlinear component that includes a diode exhibiting resistive and capacitive behavior.

The diagram 300 illustrates the frequency, in units of GHz, on a horizontal axis 310, the real part (resistance, in units of Ohm) of the impedance on a left vertical axis 320 and the imaginary part (reactance, in units of Ohm) of the impedance in a right vertical axis 330. The horizontal axis 310 represents frequencies between about 0.8 GHz and about 2 GHz, the left vertical axis 320 represent resistance values from zero up to about 1000 Ohms, and the right vertical axis 330 represents absolute values of the reactance from zero up to about 4000 Ohms. The right vertical axis 330 represents the absolute value because the reactance of a capacitive element is typically negative.

Traces 340 and 350 illustrate the changes of the resistance and reactance, respectively, of the nonlinear component as the function of the frequency in the frequency band of interest between about 1 GHz and 2 GHz. In this band, the trace 340 shows that the nonlinear component's resistance (real part) changes from about 450 Ohm at 1 GHz to about 100 Ohm at 2 GHz, and the trace 350 shows that the absolute value of the nonlinear component's reactance (imaginary part) changes from about 3200 Ohms to about 1200 Ohms. Thus, the impedance of the nonlinear component can change to more than twofold or even threefold in the broad frequency band of interest. However, a frequency desensitizer according to one aspect of the invention can substantially compensate even such a large change of impedance of the nonlinear component. In one embodiment (shown in FIG. 2A), an R-L-C frequency desensitizing network 230 with a capacitor 232 value of about 1 pF, an inductor 234 value of about 2 nH, and a resistor 236 value of about 400 Ohm (FIG. 2A), can reduce the impedance changes across the 1 GHz band in terms of the resistance (real part) to be less than about 50% and in terms of the reactance (imaginary part) to be less than about 10%.

FIG. 4 is a schematic flow chart illustrating a method 400 of operation by a predistortion linearizer, such as predistortion linearizer 220, 240, or 260 shown in FIGS. 2A-2C, which include a nonlinear component and a frequency desensitizer that is coupled in parallel with the nonlinear component.

The predistortion linearizer receives an input signal that carries information in a frequency band (step 410). In one implementation, the frequency band has a large fractional bandwidth, such as more than about 50%, for example, about 100% or more. As an example, the input signal can be an L-Band signal generated by a MODEM and carrying digital information in a band between about 1 GHz and 2 GHz in a satellite communication system.

The predistortion linearizer uses the nonlinear component to predistort the input signal (step 420). The predistortion linearizer can predistort the input signal to compensate for AM-AM, AM-PM, or both distortions of an RF power amplifier. For example, the nonlinear component can include a diode or a transistor and can be arranged in a π-shape or T-shape attenuator that attenuates the input signal. The nonlinear component can have an impedance that changes substantially in the frequency band that carries the information. For example, the nonlinear component's impedance can change about twofold or more, such as about threefold or more.

The predistortion linearizer uses the frequency desensitizer, coupled in parallel with the nonlinear component, to compensate changes of the nonlinear component's impedance in the frequency band carrying the information (step 430). For example, the frequency desensitizer can include a series or parallel R-L-C resonance circuit. The resonant frequency and the resistance of the R-L-C circuit can have values that cause the R-L-C circuit to substantially compensate for the changes caused by the frequency dependence of the nonlinear component.

Thus, with the method 400, the predistortion linearizer can provide substantially frequency-indendent predistortion throughout a large fractional bandwidth, for example, in an L-Band satellite communication signal.

FIG. 5 is a schematic flow chart illustrating a method 500 to design a predistortion linearizer, such as predistortion linearizer 220, 240, or 260 shown in FIGS. 2A-2C, which include a nonlinear component and a frequency desensitizer. The method 500 can be performed by an operator or, at least in part, by a computer having a processor and a memory, and executing software applications including computer instructions configured to design electric circuits.

First, an impedance change of the nonlinear component is determined in a target frequency band (step 510). For example, a circuit model of the nonlinear component can be simulated using a software application to measure impedance changes in the target frequency band.

Next, a frequency desensitizer configuration is designed to compensate effects of the impedance change of the nonlinear component due to frequency changes in the target band (step 520). For example, an R-L-C circuit model of the frequency desensitizer can be designed using a software application. The software application can also be applied to the circuit in which the frequency desensitizer is connected to the nonlinear element, e.g., in parallel; the software application can simulate the combined operation of the nonlinear element and the frequency desensitizer, and make changes in the design as necessary. In one implementation, a resonant frequency of the R-L-C circuit is selected according to the magnitude of the corrections necessary for the compensation in the target band. For large corrections, the resonant frequency can be close to the target band. For smaller corrections, the resonant frequency can be farther away from the target band.

Finally, the frequency desensitizer is optimized to desensitize the frequency dependence of the nonlinear component in the target band (step 530). For example, a circuit model of the predistortion linearizer, including both the nonlinear component and the frequency desensitizer, can be simulated using a software application and make changes in the parameters or the design as necessary.

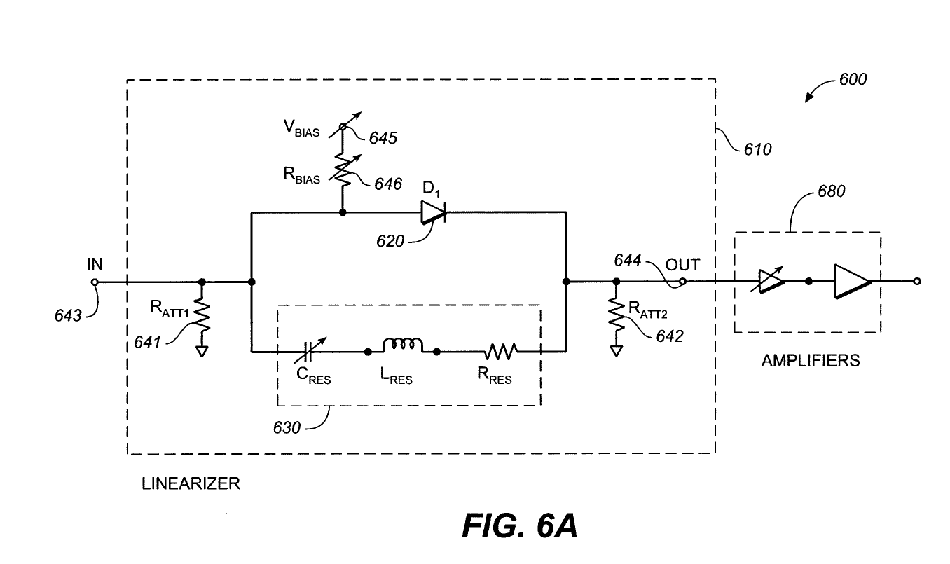

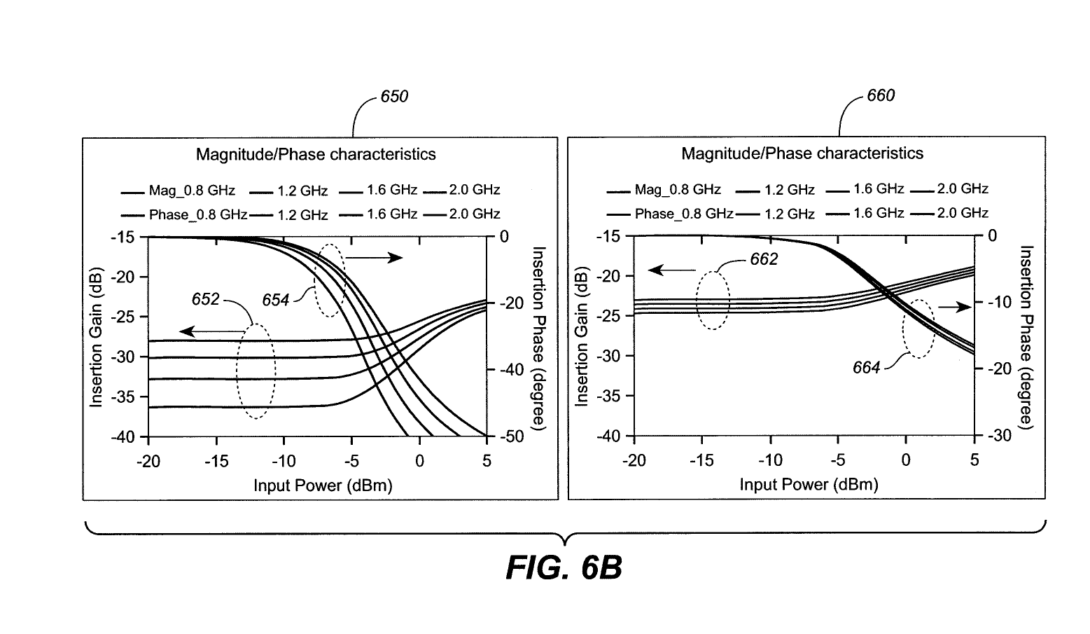

The different aspects of the present invention can be implemented in several architectures for the broadband predistortion linearizers. As an example, in one aspect, these broadband predistorter architectures can include diodes as nonlinear components and R-L-C resonators as frequency desensitizers. Exemplary embodiments of such broadband predistorters are described below with reference to FIGS. 6A-10.

FIG. 6A illustrates a first exemplary system 600. The system 600 includes a predistortion linearizer 610 and amplifiers 680. The predistortion linearizer 610 is configured to predistort a drive signal to compensate for AM-AM and AM-PM distortions of the amplifiers 680.

The predistortion linearizer 610 includes a diode 620 (D₁), a series R-L-C resonator 630 connected in parallel with the diode 620, two resistors 641 and 642 (R_{ATT1-2}), and a bias circuitry with a supply voltage 645 (V_{BIAS}) and a variable resistor 646 (R_{BIAS}). For clarity, DC blocking capacitors and high frequency chokes, which stop the propagation of high frequency signals through and bypass DC signal, are omitted in FIG. 6A.

In the predistortion linearizer 610, the diode 620 predistorts the input signal. In general, a diode can be represented by its current-voltage relationship (I-V curve), known as a diode equation, and generally modeled by a nonlinear conductance (or resistance) as a function of its input drive signal and a nonlinear junction capacitance. Optionally, more parasitic parameters can be added for a more detailed analysis. Due to the diode's nonlinear conductance, the R-L-C resonator circuitry 630 simply forms a power-dependent π-shape variable attenuator in conjunction with the resistors (R_{ATT1-2}) 641 and 642 between an input port (IN) 643 and an output port (OUT) 644. The conductance of the diode, which is a derivative of its current with respect to the voltage across, exponentially increases as the voltage becomes larger. The insertion loss of the attenuator drops at higher drive levels, thereby providing a gain expansion, which will compensate for the gain compression seen in a typical power amplifier. The phase response of the input-to-output transfer characteristic of the nonlinear junction capacitance of the diode changes as the strength of the input signal varies, and such nonlinear behavior can provide a desirable reciprocal phase response to counteract that of the subsequent amplifier. However, the impedance of the junction capacitance depends strongly on the frequency of operation. In general, such strong dependence upon the frequency for reactive parameters tends to be a main limiting factor to realize an extremely broadband predistortion, even if it can be mitigated to some degree over a relatively narrow frequency bandwidth.

With respect to the R-L-C resonator 630 coupled in parallel with the diode D₁ 620, both the resonant frequency of the resonator 630 and the effective net reactance at different frequencies are determined based on the values of the capacitor (C_{RES}) and inductor (L_{RES}) in use. In the R-L-C resonator 630, the resistor (R_{RES}) is connected in series with the capacitor (C_{RES}) and inductor (L_{RES}) and determines not only the quality factor of the resonator 630 but also the slope of net reactance over frequencies of interest. The frequency-dependency of the diode's junction capacitance can be desensitized by the R-L-C resonator section 630 with careful choice of values of the resistor (R_{RES}), capacitor (C_{RES}), and inductor (L_{RES}). The combination of the nonlinear diode 620 and the frequency-desensitizing R-L-C resonator 630 enables one to realize a predistortion linearizer to cover a very wide frequency range.

The architecture of the predistortion linearizer 610 allows simple, compact, and cost-effective implementations because it advantageously involves passive components: a nonlinear diode, a capacitor, an inductor, and the resistors shown in FIG. 6A without any need for broadband power dividers or combiners, phase shifters, attenuators, etc. The present invention is not limited to the specific architecture of the π-shape attenuator shown in FIG. 6A and it could be extended to other architectures (e.g., to a T-shaped architecture, see FIG. 2B) including a circuit that incorporates both the diode 620 and the R-L-C resonator 630. In addition, other types of nonlinear components such as field effect transistors (FETs) or bipolar junction transistors (BJTs) can be used in place of, or in conjunction with the diode 620 shown here.

In the predistortion linearizer 610, the shape of diode's I-V curve can be controlled by the R_{BIAS} 646, that can provide an independent gain control. The supply voltage 645 (V_{BIAS}) appears across the resistor R_{BIAS} 646 and the diode 620. The R_{BIAS} 646 provides a negative feedback on the diode's current-voltage relationship: the more diode current flows from the DC supply, the less diode voltage appears because more voltage drops across the R_{BIAS} 646. This results in decreasing the diode current and changing the exponential increase of its current to one that has less sensitive dependence on the voltage. Because the slope of the I-V curve is directly proportional to its conductance, the independent control of the gain can be achieved by controlling the R_{BIAS} 646. This is very desirable for broadband predistortion linearizers so as to neutralize amplifiers that require different AM-AM conversions over different frequency bands.

In the predistortion linearizer 610, the phase response of the input-to-output transfer function is mainly determined by the total capacitance generated by two signal paths with the diode 620 and the resonator 630. The phase control can be independently accomplished by changing the capacitance of C_{RES} in the frequency-desensitizing R-L-C resonator 630.

Additionally, in the predistortion linearizer 610, the turn-on voltage of the diode 620 is substantially determined by both the supply voltage (V_{BIAS}) 645 as well as the induced DC bias voltage from the input signal. The critical input drive power, at which the reciprocal transfer function of the predistorter in terms of AM-AM and AM-PM begins to occur, can be controlled by the control voltage V_{BIAS} 645. Thus, the predistortion linearizer 610 can provide a wide dynamic range, while preserving the AM-AM and AM-PM conversions required for the predistortion. Not only is this feature advantageous for broadband predistortion linearizers, but it can also substantially eliminate any need for either a variable amplifier or a variable attenuator that are used in conventional approaches to adjust an input drive power to the predistorter.

FIG. 6B shows schematic diagrams 650 and 660 which illustrate the magnitude and phase characteristics of the linearizer 610 without and with the R-L-C resonator 630, respectively. The diagrams 650 and 660 illustrate the input power (in the range of about −20 dBm to about 5 dBm) on their horizontal axis, the gain of the linearizer 610 on their left vertical axes (in units of dB), and the phase of the linearizer 610 on their right vertical axes (in units of degrees).

The diagram 650 includes traces 652 and 654 illustrating how gain and phase, respectively, change in the linearizer 610 without the R-L-C resonator 630. Traces 652 illustrate the gain of the linearizer 610 as a function of input power for frequencies 0.8 GHz, 1.2 GHz, 1.6 GHz, and 2.0 GHz. The traces 652 show that the gain of the linearizer 610 without the R-L-C resonator 630 changes substantially as the frequency changes from about 1.0 GHz to about 2.0 GHz, which is the bandwidth of the L-Band in satellite communication applications. Traces 654 illustrate the phase of the linearizer 610 without the R-L-C resonator 630 as a function of input power for frequencies 0.8 GHz, 1.2 GHz, 1.6 GHz, and 2.0 GHz. The traces 654 show that the phase of the linearizer 610 without the R-L-C resonator 630 changes substantially as the frequency changes from about 1.0 GHz to about 2.0 GHz, which is the bandwidth of the L-Band in satellite communication applications. Due to the large frequency dependence shown by traces 652 and 654, the linearizer 610 would not be well suited to operate on the L-Band without the R-L-C resonator 630.

The diagram 660 includes traces 662 and 664 illustrating how gain and phase, respectively, change in the linearizer 610 with the R-L-C resonator 630 included. Traces 662 illustrate the gain of the linearizer 610 as a function of input power for frequencies 0.8 GHz, 1.2 GHz, 1.6 GHz, and 2.0 GHz. The traces 662 show that the gain of the linearizer 610 does not change substantially as the frequency changes from about 1.0 GHz to about 2.0 GHz, which is the bandwidth of the L-Band in satellite communication applications. Traces 664 illustrate the phase of the linearizer 610 as a function of input power for frequencies 0.8 GHz, 1.2 GHz, 1.6 GHz, and 2.0 GHz. The traces 664 show that the phase of the linearizer 610 does not change substantially as the frequency changes from about 1.0 GHz to about 2.0 GHz, which is the bandwidth of the L-Band in satellite communication applications. Due to the lack of substantial frequency dependence as shown by traces 662 and 664, the linearizer 610 can operate on the L-Band by using the simple R-L-C resonator 630.

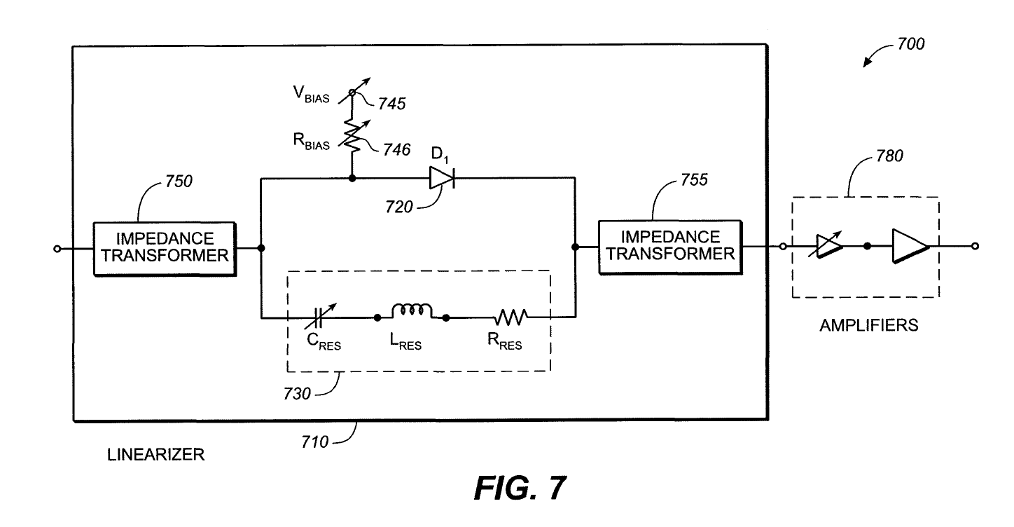

FIG. 7 illustrates a system 700 in another exemplary implementation of the invention. The system 700 includes a predistortion linearizer 710 and amplifiers 780. The predistortion linearizer 710 is configured to predistort a drive signal to compensate for AM-AM and AM-PM distortions of the amplifiers 780.

The predistortion linearizer 710 includes a diode 720 (D₁), a series R-L-C resonator 730 connected in parallel with the diode 720, two impedance transformers 750 and 755, and a bias circuitry with a supply voltage (V_{BIAS}) 745 and a variable resistor (R_{BIAS}) 746. For clarity, DC blocking capacitors and high frequency chokes, which stop the propagation of high frequency signals through and bypass DC signal, are omitted in FIG. 7.

The predistortion linearizer 710 operates similar to the predistortion linearizer 610 described above with reference to FIG. 6A. However, unlike the structure of the predistortion linearizer 610, the predistortion linearizer 710 includes impedance transformers 750 and 755 to provide impedance matchings between the predistortion linearizer and other sub-circuits in the system 700. The impedance transformers 750 and 755 can cover the frequency bandwidth of interest and may be comprised of transmission lines and lumped elements such as capacitors, inductors, and resistors.

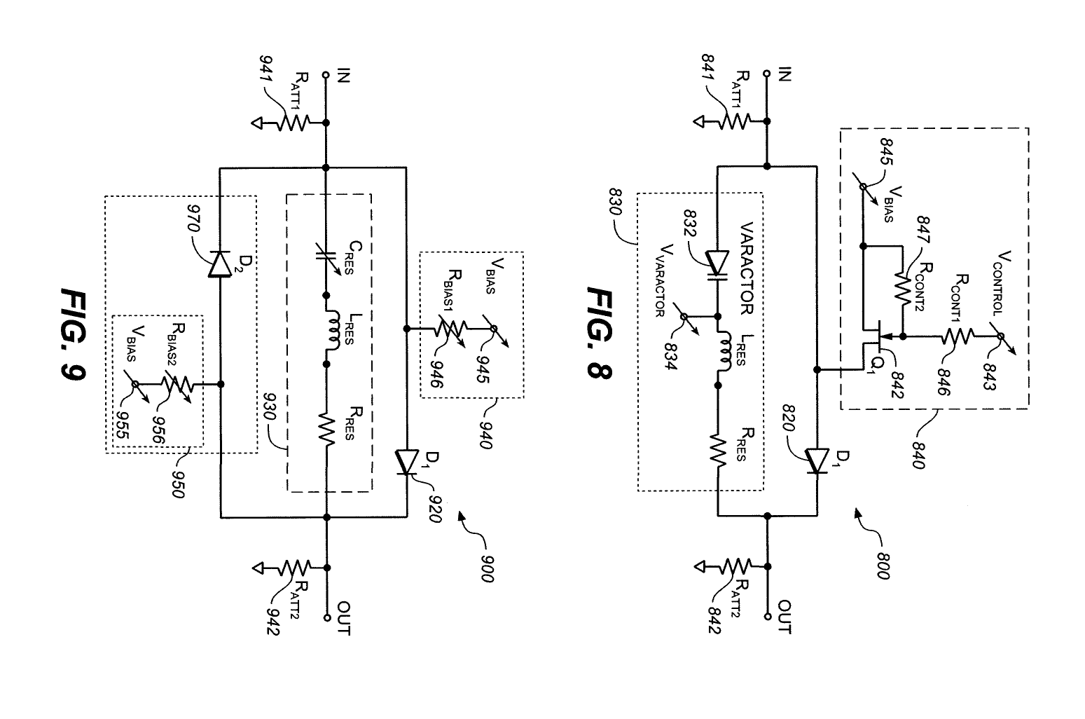

FIG. 8 illustrates a predistortion linearizer 800 in an exemplary implementation of the invention. The predistortion linearizer 800 is configured to predistort a drive signal to compensate for AM-AM and AM-PM distortions of power amplifiers.

The predistortion linearizer 800 includes a diode (D₁) 820, a series R-L-C resonator 830 connected in parallel with the diode 820, two resistors (R_{ATT1-2}) 841 and 842, and a bias circuitry 840 with a supply voltage (V_{BIAS}) 845. For clarity, DC blocking capacitors and high frequency chokes, which stop the propagation of high frequency signals through and bypass DC signal, are omitted in FIG. 8.

The predistortion linearizer 800 is a variation of the predistortion linearizer 610 (shown in FIG. 6A). In the bias circuitry 840, a junction FET (JFET) 842 and resistors 846 and 847 (R_{CONT1-2}) are incorporated in conjunction with the diode supply voltage 845 in order to implement the variable resistor (R_{BIAS}) 646 of the predistortion linearizer 610 (FIG. 6A). The channel resistance of the depletion type JFET 842 becomes proportional to the magnitude of a control voltage (V_{CONTR0L}) 843. The more negative the control voltage (V_{CONTR0L}) 843 is applied to the gate terminal of the JFET 842, the wider the depletion region in the channel area is created. This results in a higher resistance from the JFET 842 so that the slope of the diode's I-V curve becomes less steep and consequently the AM-AM conversion can be controlled by the control voltage 843. This approach to implement a variable resistor is not limited to using the JFET 842 but can incorporate other types of components. In the bias circuitry 840, the resistors 846 and 847 (R_{CONT1-2}) in conjunction with the JFET 842 can eliminate the dependency of an achievable resistance on the voltage across its drain and source terminals, and the resistance depends substantially upon the control voltage (V_{CONTROL}) 843 and device parameters such as a pinch-off voltage.

In the predistortion linearizer 800, the R-L-C resonator 830 uses a varactor 832 to provide a voltage-controlled capacitance with respect to its control voltage (V_{VARACTOR}) 834. The varactor 832 corresponds to the variable capacitor (C_{RES}) of the R-L-C resonator 610 (FIG. 6A) to provide phase control.

FIG. 9 illustrates a predistortion linearizer 900 in another exemplary implementation of the invention. The predistortion linearizer 900 is configured to predistort a drive signal to compensate for AM-AM and AM-PM distortions of a power amplifier.

The predistortion linearizer 900 includes a first diode 920 (D₁), a second diode 970 (D₂), a series R-L-C resonator 730 connected in parallel with the diode 920, two resistors 941 and 942 (R_{ATT1-2}), a first bias circuit 940 with a supply voltage (V_{BIAS}) 945 and a variable resistor (R_{BIAS}) 946, and a second bias circuit 950 with a supply voltage (V_{BIAS}) 955 and a variable resistor (R_{BIAS2}) 956. For clarity, DC blocking capacitors and high frequency chokes, which stop the propagation of high frequency signals through and bypass DC signal, are omitted in FIG. 9.

The predistortion linearizer 900 is a variation of the predistortion linearizer 610 (shown in FIG. 6A). The predistortion linearizer 900 includes the additional diode 970 (D₂), which can be substantially identical to the diode 920 (D₁). The diode 920 and the additional diode 970 form a pair of anti-parallel diodes in parallel with the R-L-C resonator 930. Nonlinear I-V characteristic of a single-ended diode contains significant amount of power at higher order harmonic frequencies as well as at a fundamental frequency. Thus, it is typically advantageous to have the fundamental frequency signal with an appropriate amount of power at the 3^{rd} harmonics to neutralize an amplifiers' distortion. The 2^{nd} harmonics signal, which appears at the output of the diode 920 due to its exponential I-V relationship, causes undesirable even-order distortions of amplifiers. With respect to the 2^{nd} harmonic output signal, in the predistortion linearizer 900, the output signals at the 2^{nd} harmonic frequencies from both anti-parallel diodes 920 and 970 are out-of-phase because of their polarities so that they do not appear at the output of the linearizer 900 and are minimally injected into the following amplifiers. Due to intrinsic parameters such as the nonlinear conductance and nonlinear junction capacitance of the additional diode 970 (D₂), the values of the resistance (R_{RES}), the capacitance (C_{RES}), and the inductance (L_{RES}) in the R-L-C resonator 930 can be further optimized to minimize frequency dependence of the predistortion by the linearizer 900.

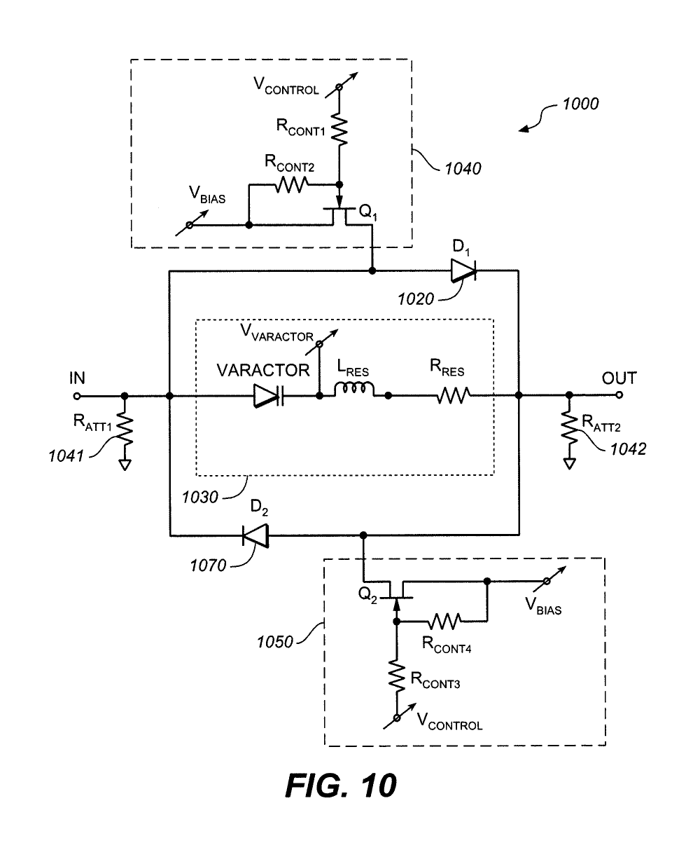

FIG. 10 illustrates a predistortion linearizer 1000 in an exemplary implementation of the invention. The predistortion linearizer 1000 is configured to predistort a drive signal to compensate for AM-AM and AM-PM distortions of power amplifiers.

The predistortion linearizer 1000 includes a first diode 1020 (D₁), a second diode 1070 (D₂), a series R-L-C resonator 1030 connected in parallel with the first and second diodes 1020 and 1070, two resistors 1041 and 1042 (R_{ATT1-2}), a first bias circuit 1040 and a second bias circuit 1050 connected respectively to the first and second diodes 1020 and 1070. For clarity, DC blocking capacitors and high frequency chokes, which stop the propagation of high frequency signals through and bypass DC signal, are omitted in FIG. 10.

The predistortion linearizer 1000 is a combination of two of the structures shown in FIGS. 8 and 9. The predistortion linearizer 1000 is similar to the predistortion linearizer 900 (shown in FIG. 9), where the variable resistances 946 and 956 (R_{BIAS1-2}) of the bias circuits 940 and 950 and the variable capacitance of the R-L-C resonator 930 are implemented by the JFET 842 circuit and the varactor 832 circuit of the predistortion linearizer 800 (shown in FIG. 8), to provide independent gain and phase control, respectively.

The invention has been described with reference to particular embodiments. However, persons skilled in the art would understand that the invention can be implemented using a number of different variations. For example, although the present description focused on satellite communication systems, the invention can be implemented in other systems that require minimizing frequency dependence of non-linear components. Also, particular circuits with particular circuit elements have been shown to illustrate different aspects of the invention, but the invention can be implemented using other circuits with different circuit elements. For example, the nonlinear component can include one or more capacitors or inductors to provide the desired AM-AM or AM-PM characteristics. Also, steps in the described methods can be implemented in a different order and still provide desirable results.

What is claimed is:

1. A predistortion linearizer for providing predistorted signals to a power amplifier, the linearizer comprising:
an input to receive a drive signal carrying information in a frequency band;
a nonlinear component coupled to the input and configured to predistort the drive signal as a function of the drive signal's amplitude, the nonlinear component having an impedance substantially changing in the frequency band;
a frequency desensitizer coupled in parallel with the nonlinear component and configured to compensate the impedance changes of the nonlinear component within the frequency band; and
an output to provide the predistorted drive signal.

2. The predistortion linearizer of claim 1, wherein the frequency desensitizer includes a resonator including a capacitor, an inductor and a resistor.

3. The predistortion linearizer of claim 2, wherein the capacitor and the inductor are connected in series.

4. The predistortion linearizer of claim 2, wherein the capacitor and the inductor are connected in parallel.

5. The predistortion linearizer of claim 2, wherein the resonator has a resonance frequency above the frequency band.

6. The predistortion linearizer of claim 1, wherein the frequency band has a fractional bandwidth that is larger than 50%.

7. The predistortion linearizer of claim 6, wherein the frequency band has a fractional bandwidth that is about or larger than 100%.

8. The predistortion linearizer of claim 7, wherein the frequency band is between about 1 GHz and 2 GHz.

9. The predistortion linearizer of claim 1, further comprising two resistors that form a non-linear attenuator with the nonlinear component.

10. The predistortion linearizer of claim 9, wherein the non-linear attenuator includes a π-shape or T-shape attenuator.

11. The predistortion linearizer of claim 9, further comprising a first impedance transformer to provide impedance matching with the input and a second impedance transformer to provide impedance matching with the output.

12. The predistortion linearizer of claim 1, wherein the nonlinear element is configured to generate AM-AM and AM-PM conversion characteristics that are reciprocal to those of the power amplifier.

13. The predistortion linearizer of claim 1, wherein the nonlinear element includes a diode.

14. The predistortion linearizer of claim 13, wherein the nonlinear element includes a pair of anti-parallel diodes.

15. The predistortion linearizer of claim 1, further comprising a bias circuit configured to bias the diode as a function of a variable supply voltage.

16. The predistortion linearizer of claim 15, wherein the bias circuit includes a JFET.

17. The predistortion linearizer of claim 1, wherein the nonlinear element includes a transistor.

18. The predistortion linearizer of claim 1, wherein the frequency desensitizer includes a varactor.

19. A method for providing predistorted signals to a power amplifier using a predistortion linearizer comprising:
receiving a drive signal carrying information in a frequency band at an input section of the predistortion linearizer;
predistorting the drive signal as a function of the drive signal's amplitude using a nonlinear component, wherein the nonlinear component is coupled to the input and configured to predistort the drive signal, the nonlinear component having an impedance substantially changing in the frequency band;
compensating for the impedance changes of the nonlinear component within the frequency band by using a frequency desensitizer that is coupled in parallel with the nonlinear component; and
outputting the predistorted drive signal through an output section of the predistortion linearizer.
